(19) United States
(12) Patent Application Publication
(10) Pub. No.: US 2019/0113723 A1
(43) Pub. Date: Apr. 18, 2019

(54) HIGH NA (NUMERICAL APERTURE) RECTANGULAR FIELD EUV CATOPTRIC PROJECTION OPTICS USING TILTED AND DECENTERED ZERNIKE POLYNOMIAL MIRROR SURFACES

(71) Applicant: Nikon Corporation, Tokyo (JP)

(72) Inventor: David M. Williamson, Tucson, AZ (US)

(73) Assignee: Nikon Corporation, Tokyo (JP)

(21) Appl. No.: 16/217,933

(22) Filed: Dec. 12, 2018

Related U.S. Application Data
(63) Continuation of application No. 14/171,672, filed on Feb. 3, 2014.
(60) Provisional application No. 61/760,547, filed on Feb. 4, 2013.

(51) Int. Cl. G02B 17/06; G03F 7/20

(52) U.S. Cl. CPC G02B 17/0657; G03F 7/70233

(57) ABSTRACT

A catoptric system for EUV lithography includes six freeform reflective surfaces that are specified based on fringe Zernike polynomials. Each of the surfaces is tilted and/or decentered in a meridian plane and with respect to a common axis so that image and object planes are parallel. Rectangular fields can be imaged with image space numerical aperture of at least 0.5.

### CROSS REFERENCE TO RELATED APPLICATION

This application is a continuation of U.S. patent application Ser. No. 14/171,672, filed Feb. 3, 2014, which claims the benefit of U.S. Provisional Application No. 61/760,547, filed Feb. 4, 2013, both of which are incorporated herein by reference.

### FIELD

The disclosure pertains to high numerical optical systems for lithography.

### BACKGROUND

Pattern-transfer systems using extreme ultraviolet radiation (EUV) can be used to transfer dense patterns having fine features from a reticle to sensitized substrate. Optical systems that can image portions of a reticle are generally reflective (catoptric). EUV sources tend to offer limited EUV power, and efficient use of EUV source power is required in practical systems. Conventional multi-element catoptric systems generally exhibit asymmetric aberrations, limited numerical apertures, and curved image fields. Such conventional systems are disclosed in Mann et al., U.S. Pat. No. 8,169,694 and Mann et al., U.S. Patent Application Publication 20120008124.

Conventional EUV projection optical systems use an annular field of view and rotational symmetry to minimize the variations of aberrations with field position. If the numerical apertures (NAs) of such conventional systems are to be increased, the annular field becomes disadvantageous, particularly as the distance of the annular field from the optical axis increases with NA, thereby further increasing higher-order aberrations. The annular field in combination with a high NA tends to increase the difficulty of fully correcting for reticle obliquity effects caused by non-telecentric illumination that varies its orientation around the field.

### SUMMARY

Catoptric optical systems comprise a plurality of reflective surfaces situated along a common axis from an image to an object. Each of the surfaces can be offset and tilted with respect to the common axis so as to be symmetric about a meridian plan. The reflective surfaces are configured to image a rectangular area of an object to a rectangular image area at an image space numerical aperture of at least 0.5. In some examples, the reflective surfaces are freeform surfaces such as fringe Zernike polynomial-based surfaces, and in some cases based on bilaterally symmetric fringe Zernike polynomials. In some examples, the plurality of reflective optical surfaces includes first, third, fourth, and fifth reflective surfaces having curvatures of a first sign, and second and sixth reflective surfaces having curvatures of an opposite sign. In a representative example, the plurality of reflective optical surfaces includes exactly six reflective surfaces, each of which is decentered and tilted so as be symmetric with respect to a meridian plane.

Projection systems and pattern transfer methods using such optical systems are also provided.

The foregoing and other objects, features, and advantages of the disclosure will become more apparent from the following detailed description, which proceeds with reference to the accompanying figures.

### BRIEF DESCRIPTION OF THE DRAWINGS

FIG. 1 is a schematic meridian plane sectional scale drawing of a six mirror EUV optical system configured to produce a 4:1 demagnification. Dimensions are summarized in the accompanying tables. Mirror apertures required at some surfaces to transmit EUV from an object plane to an image plane, without obscuration, are not shown.

FIG. 2 is a schematic diagram of an immersion microlithography system, which is a first example of a precision system including a stage assembly as described herein.

FIG. 3 is a schematic diagram of an extreme-UV microlithography system, which is a second example of a precision system including a stage assembly as described herein.

FIG. 4 is a process-flow diagram depicting exemplary steps associated with a process for fabricating semiconductor devices.

FIG. 5 is a process-flow diagram depicting exemplary steps associated with a processing a substrate (e.g., a wafer), as would be performed, for example, in the process shown in FIG. 4.

### BRIEF DESCRIPTION OF THE TABLES

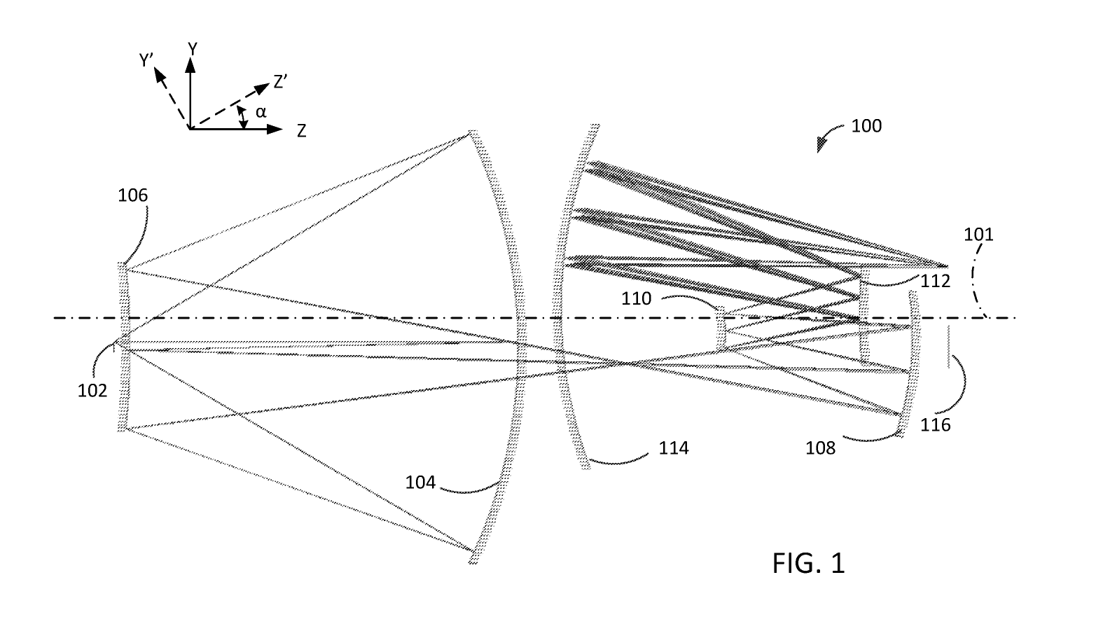

Table 1 is a surface listing for the mirror system of FIG. 1, including surface curvatures, thicknesses (separations), apertures, and surface types. Dimensions for this and all tables are in mm. Thicknesses are axial distances to the next surface. Some surfaces are shown with multiple separations that are to be summed to find actual element separations. For example, surface 3 shows surface separations of 122.557 mm and −321.9975 mm; these multiple separations are introduced to simplify evaluations, and an actual separation is a sum of these two separations. All surfaces are fringe Zernike surfaces denoted as S-1, S-2, etc., with values shown in Tables 2-7 below. Surface curvatures use a sign convention in which a positive radius or curvature indicates a center of curvature is to the right of the surface and a negative radius or center of curvature indicates the center of curvature is to the left, with FIG. 1 situated so that surface 102 is at the left. Tilts and decenters are with respect to the right handed coordinate axes shown in FIG. 1. An X-axis is into the plane of the drawing and is not shown. The surface listing (object to image) produces a 4:1 magnification as shown, but for 1:4 imaging, the surface listing is reversed.

Tables 2-7 list parameters for surface types S-1 to S-6, including surface curvatures and fringe Zernike polynomial coefficients. The selected fringe Zernike coefficients are associated with bilaterally symmetric fringe Zernike polynomials. For convenience, surface curvatures (reciprocals of surface radii) are included even though surface radii are listed in Table. 1.

Table 8 summarizes tilts and decenters. All reflective surfaces of Table 1 are tilted and decentered. As noted above, coordinate axes and tilts are illustrated with the coordinate axes of FIG. 1. In the example of FIG. 1, all tilts are in the XY-plane about the X-axis, and are denoted as a.

Table 9 lists the order of surface decenterings and displacements. A decenter defines a new coordinate system (displaced and/or rotated) in which subsequent surfaces are defined. Surfaces following a decenter are aligned on a local mechanical axis (z-axis) of a new coordinate system. While a new mechanical axis remains in use until changed by another decenter, in the example of FIG. 1, all decenters are followed by a return (RETU) operation, in which the new coordinate system is restored. Alpha, beta, and gamma are in degrees, but the only non-zero values in this example are for alpha (a).

### DETAILED DESCRIPTION

This disclosure pertains to catoptric projection optics, particularly for EUV lithography. In one example, a 0.5 NA 6-mirror catoptric projection optical system is disclosed having an instantaneous rectangular field of view of 26×1 mm and a central obscuration in the aperture for use in an EUV step-and-scan lithography tool. This system uses mirror surfaces described by Zernike polynomials containing only terms that are bilaterally symmetrical about a meridian plane (the plane of FIG. 1). The mirrors are tilted and decentered in this meridian plane to eliminate beam obscuration at the edges of the aperture and to achieve a non-telecentric entrance pupil at the reticle, while minimizing or reducing the off-axis field distance and ray incidence angles on the mirrors. This minimizes or reduces central pupil obscuration and provides an obliquity effect on the reticle that is invariant with field position. In other examples, EUV projection optical systems have NA of up to at least 0.5 and small residual aberrations and ray incidence angles on the mirrors. Such projection optical systems are configured to facilitate reticle corrections for obliquity factors, reduce pupil obscuration and reduce higher-order aberrations at high NA.

The mirror tilts and decenters are constrained such that the object and image planes are parallel to each other to facilitate the scanning reticle and wafer stages. In this embodiment, so-called Fringe Zernike mirror surfaces are used, but so-called Y-Zernike polynomials, Forbes freeform surfaces, or other types of orthogonal polynomials may be used. Orthogonal polynomials are preferred because they facilitate correction of higher-order aberrations that arise at higher numerical apertures with rectangular field shapes. However, other types of freeform surfaces, such as non-uniform rational B-splines (NURBS), may also be used.

For convenient description, reflective surface characteristics are listed in the accompanying tables in an order from an image to an object along an axis. As shown in FIG. 1, an image surface is at a left hand side of FIG. 1, and an object surface is at a right hand side. In some cases, the reflective surfaces are referred to in a physical order in which they are arranged along an axis from an image to an object or from an object to an image. Such an ordering refers to physical locations, and radiation may be transmitted through apertures in an axially subsequent surface without being reflected or refracted. In addition, the tables (see Table 9) occasionally refer to certain surfaces as refractive, but, as used herein, this includes reflective surfaces.

With reference to FIG. 1, a catoptric optical system 100 includes, from an image surface 102 to an object surface 116 along an axis 101 and in a meridian plane, a first reflective surface 104, a second reflective surface 106, a third reflective surface 108, a fourth reflective surface 110, a fifth reflective surface 112, and a sixth reflective surface 114. The reflective surfaces 104, 106, 108, 110 have negative curvatures, and reflective surfaces 112, 114 have positive curvatures. The reflective surfaces 104, 106, 114 include apertures to avoid obscuration of imaging radiation; reflective surfaces 110, 112 can be truncated to avoid obscuration. The axis 101 is provided for convenient description only, and does not necessarily include the center of curvature of any surface.

The reflective surfaces of FIG. 1 can be freeform surfaces based on fringe Zernike polynomials or other representations of Zernike polynomials, Forbes polynomials, non-uniform B-splines, or other freeform surfaces. In some examples, bilaterally symmetric fringe Zernike surfaces are used so that aberrations are symmetric about a meridian plane. The arrangement of FIG. 1 is typically implemented so as to image a reticle (at object surface 116) to a sensitized substrate such as a wafer (at image surface 102). Each of the reflective surfaces can be tilted and decentered in the meridian plane with respect to a common axis so that image and object planes are parallel. This configuration produces a non-telecentric entrance pupil at the reticle and reduces off-axis field distances and incidence angles to the reflective surfaces. Such an arrangement reduces central pupil obscuration and produces an obliquity effect that is invariant or substantially invariant with field position.

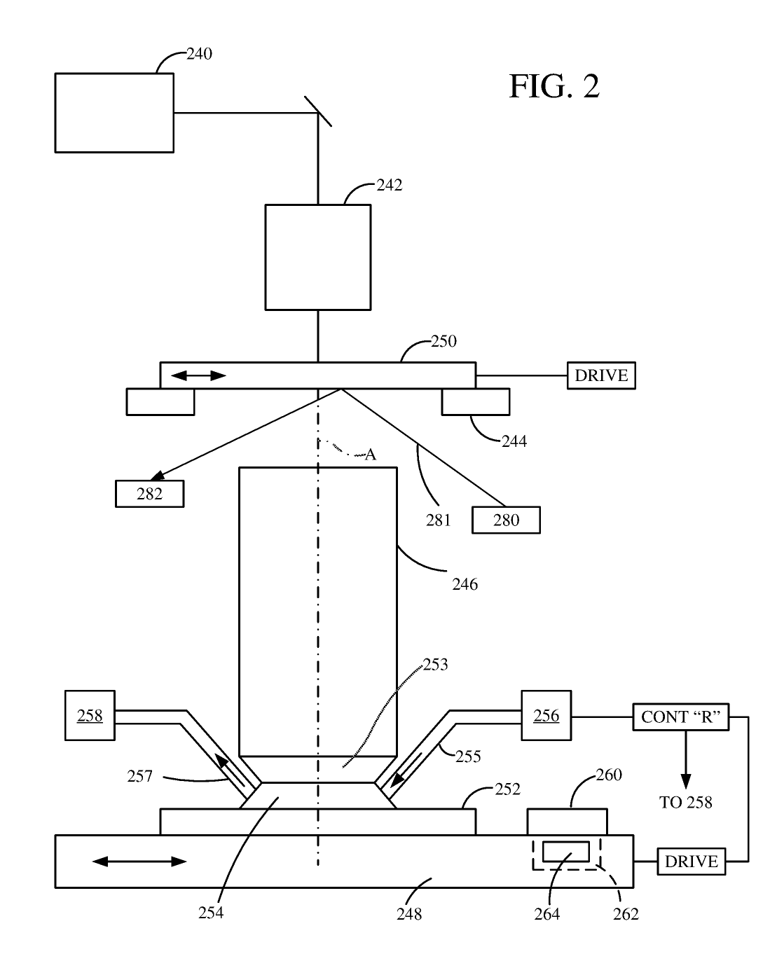

The methods and apparatus disclosed above can be used in conjunction with various precision systems such as various types of lithography systems and other wafer processing systems and methods. Turning to FIG. 2, certain features of a lithography system (an exemplary precision system) are shown, namely, a light source 240, an illumination-optical system 242, a reticle stage 244, a projection-optical system 246, and a wafer (substrate) stage 248, all arranged along an optical axis A. The light source 240 is configured to produce a pulsed beam of illumination light, such as EUV light of 13.4 nm, DUV light of 193 nm as produced by an ArF excimer laser, or DUV light of 157 nm as produced by an F2 excimer laser. The illumination-optical system 242 includes an optical integrator and at least one lens that conditions and shapes the illumination beam for illumination of a specified region on a patterned reticle 250 mounted to the reticle stage 244. The illumination light is shown as being transmitted by the patterned reticle 250, but the illumination light can be directed so as to be reflected by the patterned reticle 250 as well. The pattern as defined on the reticle 250 corresponds to the pattern to be transferred lithographically to a wafer 252 that is held on the wafer stage 248. Lithographic transfer in this system is by projection of an aerial image of the pattern from the reticle 250 to the wafer 252 using the projection-optical system 246. The projection-optical system 246 typically comprises many individual optical elements (such as those of FIG. 1) that project the image at a specified demagnification ratio (e.g., 1/4 or 1/5) on the wafer 252. So as to be imprintable, the wafer surface is coated with a layer of a suitable exposure-sensitive material termed a “resist.”

The reticle stage 244 is configured to move the reticle 250 in the X-direction, Y-direction, and rotationally about the Z-axis. To such end, the reticle stage is equipped with one or more linear motors having cooled coils as described herein. The two-dimensional position and orientation of the reticle 250 on the reticle stage 244 are detected by a laser interferometer (not shown) in real time, and positioning of the reticle 250 is effected by a main control unit on the basis of the detection thus made.

The wafer 252 is held by a wafer holder (“chuck,” not shown) on the wafer stage 248. The wafer stage 248 includes a mechanism (not shown) for controlling and adjusting, as required, the focusing position (along the Z-axis) and the tilting angle of the wafer 252. The wafer stage 248 also includes electromagnetic actuators (e.g., linear motors or a planar motor, or both) for moving the wafer in the X-Y plane substantially parallel to the image-formation surface of the projection-optical system 246. These actuators desirably comprise linear motors, one more planar motors, or both.

The wafer stage 248 also includes mechanisms for adjusting the tilting angle of the wafer 252 by an auto-focusing and auto-leveling method. Thus, the wafer stage serves to align the wafer surface with the image surface of the projection-optical system. The two-dimensional position and orientation of the wafer are monitored in real time by another laser interferometer (not shown). Control data based on the results of this monitoring are transmitted from the main control unit to a drive circuits for driving the wafer stage. During exposure, the light passing through the projection-optical system is made to move in a sequential manner from one location to another on the wafer, according to the pattern on the reticle in a step-and-repeat or step-and-scan manner.

The projection-optical system 246 normally comprises many lens or reflective elements that work cooperatively to form the exposure image on the resist-coated surface of the wafer 252. For convenience, the most distal optical element (i.e., closest to the wafer surface) is an objective lens 253. Since the depicted system is an immersion lithography system, it includes an immersion liquid 254 situated between the objective lens 253 and the surface of the wafer 252. As discussed above, the immersion liquid 254 is of a specified type. The immersion liquid is present at least while the pattern image of the reticle is being exposed onto the wafer.

The immersion liquid 254 is provided from a liquid-supply unit 256 that may comprise a tank, a pump, and a temperature regulator (not individually shown). The liquid 254 is gently discharged by a nozzle mechanism 255 into the gap between the objective lens 253 and the wafer surface. A liquid-recovery system 258 includes a recovery nozzle 257 that removes liquid from the gap as the supply 256 provides fresh liquid 254. As a result, a substantially constant volume of continuously replaced immersion liquid 254 is provided between the objective lens 253 and the wafer surface. The temperature of the liquid is regulated to be approximately the same as the temperature inside the chamber in which the lithography system itself is disposed.

Also shown is a sensor window 260 extending across a recess 262, defined in the wafer stage 248, in which a sensor 264 is located. Thus, the window 260 sequesters the sensor 264 in the recess 262. Movement of the wafer stage 248 so as to place the window 260 beneath the objective lens 253, with continuous replacement of the immersion fluid 254, allows a beam passing through the projection-optical system 246 to transmit through the immersion fluid and the window 260 to the sensor 264.

An interrogation beam source 280 is situated to direct an interrogation optical beam 281 to the reticle 250, and a detection system 282 is configured to detect a portion of the interrogation beam as modulated by the reticle 251. The detected beam can be used as described above to assess reticle distortion so that suitable system adjustments can be made to correct, prevent, or at least partially compensate distortion.

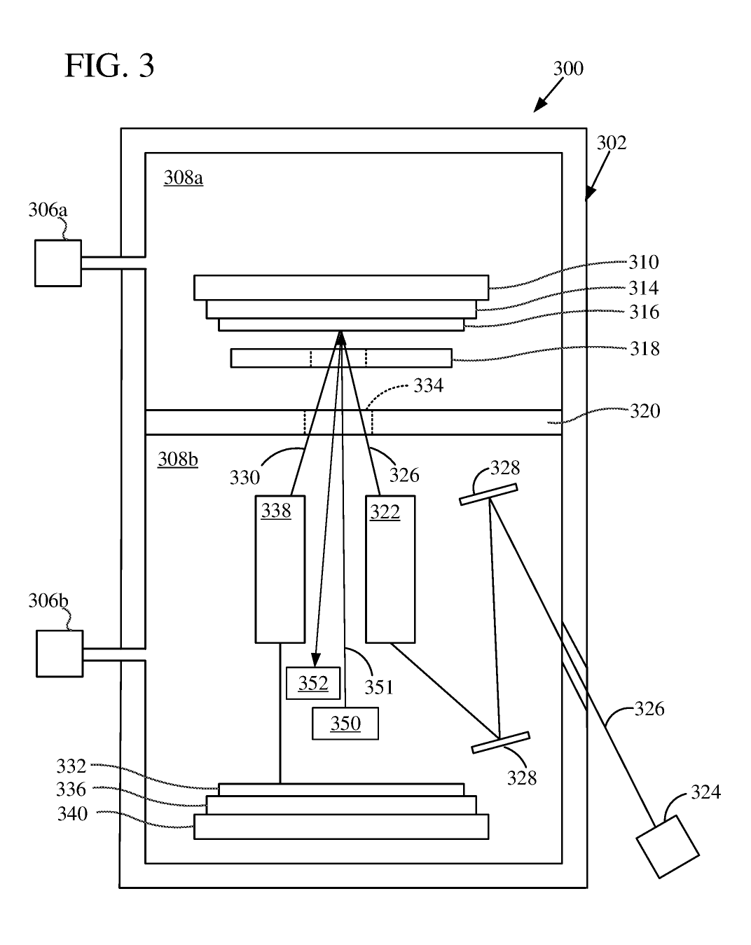

Referring now to FIG. 3, an alternative embodiment of a precision system that can include one or more electromagnetic actuators having actively cooled coils as described herein is an EUVL system 300, as a representative precision system incorporating an electromagnetic actuator. The depicted system 300 comprises a vacuum chamber 302 including vacuum pumps 306a, 306b that are arranged to enable desired vacuum levels to be established and maintained within respective chambers 308a, 308b of the vacuum chamber 302. For example, the vacuum pump 306a maintains a vacuum level of approximately 50 mTorr in the upper chamber (reticle chamber) 308a, and the vacuum pump 306b maintains a vacuum level of less than approximately 1 mTorr in the lower chamber (optical chamber) 308b. The two chambers 308a, 308b are separated from each other by a barrier wall 320. Various components of the EUVL system 300 are not shown, for ease of discussion, although it will be appreciated that the EUVL system 300 can include components such as a reaction frame, a vibration-isolation mechanism, various actuators, and various controllers.

An EUV reticle 316 is held by a reticle chuck 314 coupled to a reticle stage 310. The reticle stage 310 holds the reticle 316 and allows the reticle to be moved laterally in a scanning manner, for example, during use of the reticle for making lithographic exposures. Between the reticle 316 and the barrier wall 320 is a blind apparatus. An illumination source 324 produces an EUV illumination beam 326 that enters the optical chamber 308b and reflects from one or more mirrors 328 and through an illumination-optical system 322 to illuminate a desired location on the reticle 316. As the illumination beam 326 reflects from the reticle 316, the beam is “patterned” by the pattern portion actually being illuminated on the reticle. The barrier wall 320 serves as a differential-pressure barrier and can serve as a reticle shield that protects the reticle 316 from particulate contamination during use. The barrier wall 320 defines an aperture 334 through which the illumination beam 326 may illuminate the desired region of the reticle 316. The incident illumination beam 326 on the reticle 316 becomes patterned by interaction with pattern-defining elements on the reticle, and the resulting patterned beam 330 propagates generally downward through a projection-optical system 338 onto the surface of a wafer 332 held by a wafer chuck 336 on a wafer stage 340 that performs scanning motions of the wafer during exposure. Hence, images of the reticle pattern are projected onto the wafer 332.

The wafer stage 340 can include (not detailed) a positioning stage that may be driven by a planar motor or one or more linear motors, for example, and a wafer table that is magnetically coupled to the positioning stage using an EI-core actuator, for example. The wafer chuck 336 is coupled to the wafer table, and may be levitated relative to the wafer table by one or more voice-coil motors, for example. If the positioning stage is driven by a planar motor, the planar motor typically uses respective electromagnetic forces generated by magnets and corresponding armature coils arranged in two dimensions. The positioning stage is configured to move in multiple degrees of freedom of motion, e.g., three to six degrees of freedom, to allow the wafer 332 to be positioned at a desired position and orientation relative to the projection-optical system 338 and the reticle 316.

An EUVL system including the above-described EUV-source and illumination-optical system can be constructed by assembling various assemblies and subsystems in a manner ensuring that prescribed standards of mechanical accuracy, electrical accuracy, and optical accuracy are met and maintained. To establish these standards before, during, and after assembly, various subsystems (especially the illumination-optical system 322 and projection-optical system 338) are assessed and adjusted as required to achieve the specified accuracy standards. The projection-optical system 338 can be a catoptric system as described above. Similar assessments and adjustments are performed as required of the mechanical and electrical subsystems and assemblies. Assembly of the various subsystems and assemblies includes the creation of optical and mechanical interfaces, electrical interconnections, and plumbing interconnections as required between assemblies and subsystems. After assembling the EUVL system, further assessments, calibrations, and adjustments are made as required to ensure attainment of specified system accuracy and precision of operation. To maintain certain standards of cleanliness and avoidance of contamination, the EUVL system (as well as certain subsystems and assemblies of the system) are assembled in a clean room or the like in which particulate contamination, temperature, and humidity are controlled.

As shown in FIG. 3, an interrogation beam source 350 can be situated so as to direct an interrogation optical beam 351 to the reticle 316. A detection system 352 is situated to receive at least a portion of the interrogation beam that is reflected, refracted, diffracted, phase-shifted or otherwise modulated by interaction with the reticle 316. Based on a detector signal response to this beam portion, reticle distortion can be assessed as described above in the detection system.

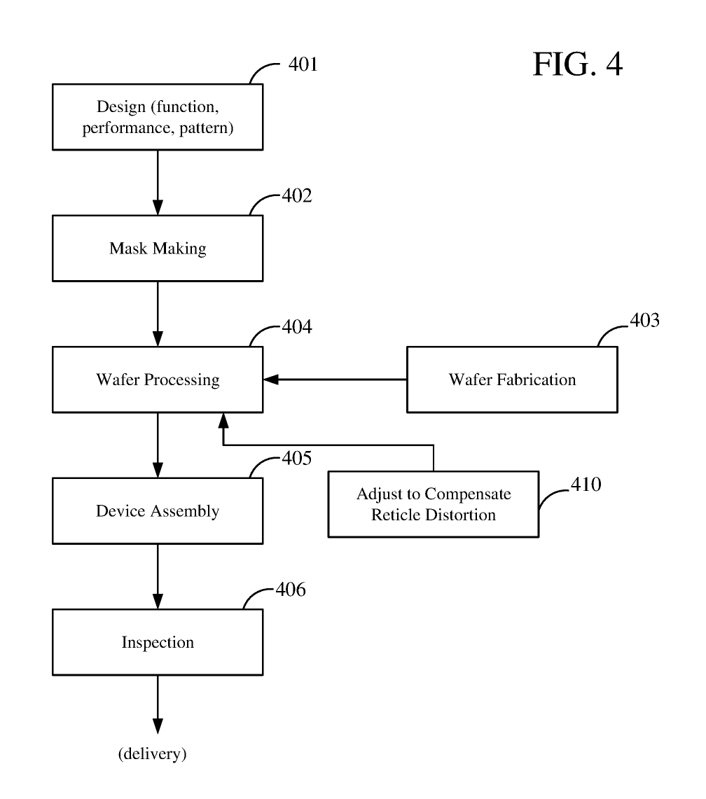

Semiconductor devices can be fabricated by processes including microlithography steps performed using a microlithography system as described above. Referring to FIG. 4, in step 401 the function and performance characteristics of the semiconductor device are designed. In step 402 a reticle (“mask”) defining the desired pattern is designed and fabricated according to the previous design step. Meanwhile, in step 403, a substrate (wafer) is fabricated and coated with a suitable resist. In step 404 (“wafer processing”) the reticle pattern designed in step 402 is exposed onto the surface of the substrate using the microlithography system. In a step 410, reticle distortion can be estimated during exposure as described above. In step 405 the semiconductor device is assembled (including “dicing” by which individual devices or “chips” are cut from the wafer, “bonding” by which wires are bonded to particular locations on the chips, and “packaging” by which the devices are enclosed in appropriate packages for use). In step 406 the assembled devices are tested and inspected.

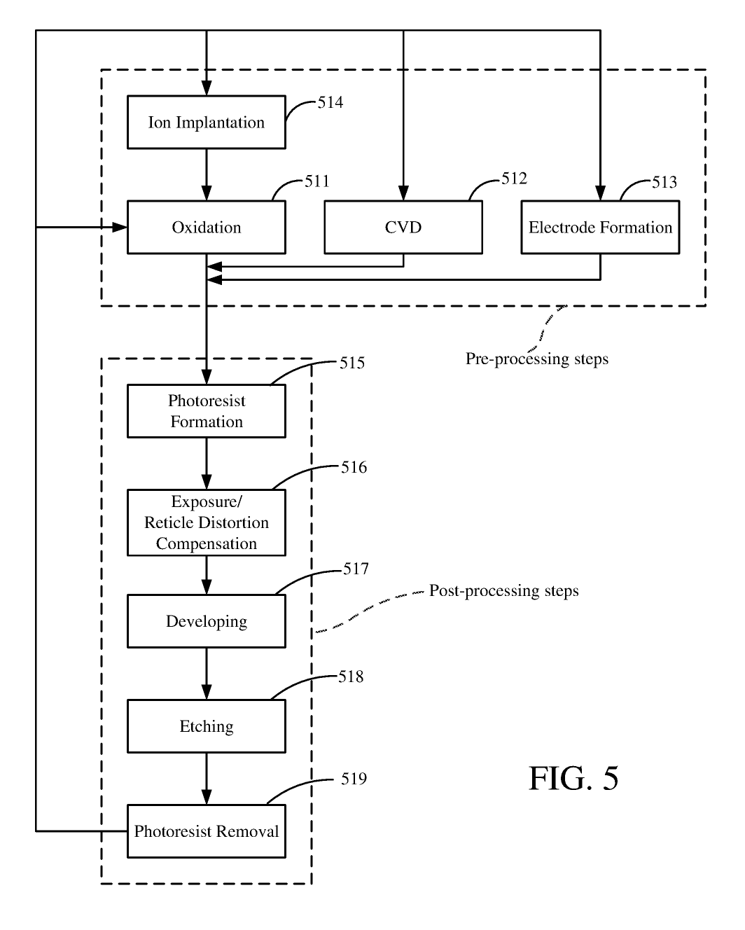

Representative details of a wafer-processing process including a microlithography step are shown in FIG. 5. In step 511 (“oxidation”) the wafer surface is oxidized. In step 512 (“CVD”) an insulator layer is formed on the wafer surface by chemical-vapor deposition. In step 513 (electrode formation) electrodes are formed on the wafer surface by vapor deposition, for example. In step 514 (“ion implantation”) ions are implanted in the wafer surface. These steps 511-514 constitute representative “pre-processing” steps for wafers, and selections are made at each step according to processing requirements.

At each stage of wafer processing, when the pre-processing steps have been completed, the following “post-processing” steps are implemented. A first post-process step is step 515 (“photoresist formation”) in which a suitable resist is applied to the surface of the wafer. Next, in step 504 (“exposure”), the microlithography system described above is used for lithographically transferring a pattern from the reticle to the resist layer on the wafer. Reticle distortion can be compensated during pattern transfer. In step 517 (“developing”), the exposed resist on the wafer is developed to form a usable mask pattern, corresponding to the resist pattern, in the resist on the wafer. In step 518 (“etching”), regions not covered by developed resist (i.e., exposed material surfaces) are etched away to a controlled depth. In step 519 (“photoresist removal”), residual developed resist is removed (“stripped”) from the wafer.

Formation of multiple interconnected layers of circuit patterns on the wafer is achieved by repeating the pre-processing and post-processing steps as required. Generally, a set of pre-processing and post-processing steps are conducted to form each layer.

The following paragraphs describe these and other aspects of the present invention in more general terms. The applicant reserves the right to direct claims to any of these aspects or any combinations thereof:

(1) Catoptric optical systems, comprising a plurality of reflective surfaces situated along a common axis from an image to an object and offset and tilted with respect to the common axis so as to be symmetric about a meridian plane, wherein the reflective surfaces are configured to image a rectangular area of an object to a rectangular image area;

(2) Catoptric optical systems such as those of paragraph (1), wherein an image space numerical aperture is at least 0.4;

(3) Catoptric optical systems such as those of paragraph (1), wherein an image space numerical aperture is at least 0.45;

(4) Catoptric optical systems such as those of paragraph (1), wherein an image space numerical aperture is at least 0.5;

(5) Catoptric optical systems such as those of paragraph (1), wherein the plurality of reflective surfaces includes at least six free form optical surfaces;

(6) Catoptric optical systems such as those of paragraph (1), wherein at least one of the free form reflective surfaces is a fringe Zernike surface described by a series of fringe Zernike polynomials;

(7) Catoptric optical systems such as those of paragraphs (1-6), wherein the plurality of reflective optical surfaces includes exactly six reflective surfaces;

(8) Catoptric optical systems such as those of paragraph (1), wherein at least one of the freeform reflective surfaces is a Forbes surface described by series of Forbes polynomials.

(9) Catoptric optical systems such as those of paragraph (5), wherein at least one of the freeform reflective surfaces is a non-uniform B-spline surface.

(10) Catoptric optical systems such as those of paragraph (5), wherein the free form reflective surfaces are fringe Zernike surfaces described by respective series of fringe Zernike polynomials;

(11) Catoptric optical systems such as those of paragraph (5), wherein the fringe Zernike polynomials are symmetric about the meridian plane.

(12) Catoptric optical systems such as those of paragraph (5), wherein the freeform reflective surfaces are fringe Zernike surfaces, Forbes polynomial surfaces, or non-uniform B-spline surfaces or combinations thereof.

(13) Catoptric optical systems such as those of paragraph (1), wherein the plurality of reflective optical surfaces includes first, third, fourth, and fifth reflective surfaces having curvatures of a first sign, and second and sixth reflective surfaces having curvatures of an opposite sign.

(14) Catoptric optical systems such as those of paragraph (13), wherein the plurality of reflective optical surfaces includes exactly six reflective surfaces.

(15) Catoptric optical systems such as those of paragraph (1), wherein at least one of the plurality of reflective surfaces is decentered and tilted in a meridian plane;

(16) Catoptric optical systems such as those of paragraph (1), wherein each of the plurality of reflective surfaces is decentered and tilted in a meridian plane.

(17) Catoptric optical systems such as those of paragraph (1), wherein the image area is a rectangular area of at least 1 mm by 26 mm;

(18) Catoptric optical systems such as those of paragraph (1), wherein an image plane and an object plane are parallel.

(19) Catoptric optical systems such as those of paragraph (1), wherein the reflective surfaces are specified by any of Tables 1-8.

(20) Pattern transfer apparatus, comprising a light source configured to irradiate a reticle; and a catoptric optical system as recited in any of paragraphs (1-19) and configured to image an irradiated portion of the reticle onto a sensitized surface.

(21) Methods, comprising arranging a plurality of freeform optical surfaces along a common axis, each of the free from surfaces offset and tilted with respect to the common axis with respect to a meridian plane so as to from an image a reticle surface in a first plane to a sensitized substrate surface in a second plane, wherein the first plane and the second plane are parallel; and irradiating the reticle so as to expose the sensitized substrate to the image of the reticle.

The above examples are provided in order to illustrate selected embodiments, but the invention is not to be limited by features in any particular embodiment. I claim all that is encompassed by the appended claims.

TABLE 1

| | | SURFACE DESCRIPTION | | | THICKNESS | APERTURE DESCRIPTION | | | |
|---|---|---|---|---|---|---|---|---|---|
| ELT | SUR | RADIUS | | | OR | DIMENSION | | | |
| NO. | NO. | X | Y | SHAPE | SEPARATION | X | Y | SHAPE | MATERIAL |
| OBJECT | | INF | | FLT | 0.0000 | | | | |

| | | | | | | | | |
|---|---|---|---|---|---|---|---|---|
| | | | | | 37.2099 | 36.770 | CIR | |
| | | | | | 929.4935 | 73.368 | CIR | |
| 1 | 1 | −1173.850 | −1173.850 | S-1 | −929.4935 | 1010.136 | CIR | REFL |
| 2 | 2 | −2162.223 | −2162.223 | S-2 | 929.4935 | 390.211 | CIR | REFL |
| | | | | | 495.5477 | 164.884 | CIR | |
| | | | | | 321.9975 | 270.329 | CIR | |
| | | | | | 122.5557 | 322.269 | CIR | |
| 3 | 3 | −705.925 | −705.925 | S-3 | −122.5557 | 337.379 | CIR | REFL |
| | | | | | −321.9975 | 413.484 | CIR | |
| 4 | 4 | −457.796 | −457.796 | S-4 | 321.9975 | 96.059 | CIR | REFL (STOP) |
| 5 | 5 | 1528.610 | 1528.610 | S-5 | −714.0301 | 233.518 | CIR | REFL |
| 6 | 6 | 1063.744 | 1063.744 | S-6 | 714.0301 | 802.803 | CIR | REFL |
| | | | | | 213.3398 | 398.241 | CIR | |
| IMAGE | | INF | | FLT | | 397.246 | | |

TABLE 2
Surface Type S-1 Fringe Zernike Surface Curvature = −0.851897E−03

| | | | | | |
|---|---|---|---|---|---|
| NRADIUS (C2): | 5.1769E+02 | ZF1 (C4): | −1.8282E−01 | ZF4 (C7): | −2.8609E−01 |
| ZF5 (C8): | 4.6351E−02 | ZF8 (C11): | 1.0254E−02 | ZF9 (C12): | −1.2670E−01 |
| ZF11 (C14): | −9.9616E−04 | ZF12 (C15): | 1.7767E−03 | ZF15 (C18): | 1.1780E−03 |
| ZF16 (C19): | −1.0953E−02 | ZF17 (C20): | −6.0354E−04 | ZF20 (C23): | 4.7753E−05 |
| ZF21 (C24): | 8.0222E−05 | ZF24 (C27): | 4.9529E−05 | ZF25 (C28): | −7.3612E−04 |
| ZF27 (C30): | −4.8996E−06 | ZF28 (C31): | −7.3803E−07 | ZF31 (C34): | 2.2262E−06 |
| ZF32 (C35): | 2.3994E−06 | ZF35 (C38): | 1.8314E−06 | ZF36 (C39): | −4.6582E−05 |
| ZF37 (C40): | −2.6730E−06 | | | | |

TABLE 3
Surface Type S-2 Fringe Zernike Surface Curvature = −0.462487E−03

| | | | | | |
|---|---|---|---|---|---|
| NRADIUS (C2): | 1.9998E+02 | ZF1 (C4): | −2.0784E−01 | ZF4 (C7): | −3.1495E−01 |
| ZF5 (C8): | 9.3429E−02 | ZF8 (C11): | 1.4000E−02 | ZF9 (C12): | −1.2640E−01 |
| ZF11 (C14): | −1.1817E−03 | ZF12 (C15): | 1.5196E−03 | ZF15 (C18): | 9.3643E−04 |
| ZF16 (C19): | −3.0279E−03 | ZF17 (C20): | −4.6357E−04 | ZF20 (C23): | 1.7360E−05 |
| ZF21 (C24): | 4.9527E−05 | ZF24 (C27): | 8.9767E−06 | ZF25 (C28): | −1.0804E−04 |
| ZF27 (C30): | −1.6849E−05 | ZF28 (C31): | 7.1988E−06 | ZF31 (C34): | 7.6932E−07 |
| ZF32 (C35): | −2.1205E−06 | ZF35 (C38): | −3.1038E−07 | ZF36 (C39): | −4.7033E−06 |
| ZF37 (C40): | −1.8549E−07 | | | | |

TABLE 4
Surface Type S-3 Fringe Zernike Surface Curvature = −0.141658E−02

| | | | | | |
|---|---|---|---|---|---|
| NRADIUS (C2): | 1.7291E+02 | ZF1 (C4): | −1.5430E−02 | ZF4 (C7): | −2.3541E−02 |
| ZF5 (C8): | 1.9173E−02 | ZF8 (C11): | 1.4968E−02 | ZF9 (C12): | −1.5043E−02 |
| ZF11 (C14): | 3.0172E−02 | ZF12 (C15): | 2.8806E−03 | ZF15 (C18): | 7.8509E−04 |
| ZF16 (C19): | −4.6751E−04 | ZF17 (C20): | 9.3867E−04 | ZF20 (C23): | 4.9393E−04 |
| ZF21 (C24): | 1.3205E−04 | ZF24 (C27): | 2.5269E−05 | ZF25 (C28): | −1.1989E−05 |
| ZF27 (C30): | −9.9966E−05 | ZF28 (C31): | 5.0844E−06 | ZF31 (C34): | 7.8101E−06 |
| ZF32 (C35): | 4.4676E−06 | ZF35 (C38): | 9.1829E−07 | ZF36 (C39): | −1.6886E−07 |
| ZF37 (C40): | 2.2861E−08 | | | | |

TABLE 5
Surface Type S-4 Fringe Zernike Surface Curvature = −0.218438E−02

| | | | | | |
|---|---|---|---|---|---|
| NRADIUS (C2): | 4.9230E+01 | ZF1 (C4): | 7.3116E−03 | ZF4 (C7): | 1.0988E−02 |
| ZF5 (C8): | −3.1204E−02 | ZF8 (C11): | −3.7236E−03 | ZF9 (C12): | 2.5461E−03 |
| ZF11 (C14): | 1.8815E−02 | ZF12 (C15): | −5.6941E−04 | ZF15 (C18): | 2.3732E−05 |
| ZF16 (C19): | 1.1486E−05 | ZF17 (C20): | −1.6500E−04 | ZF20 (C23): | −1.2970E−05 |
| ZF21 (C24): | 1.1076E−05 | ZF24 (C27): | −7.3517E−06 | ZF25 (C28): | 6.8448E−06 |
| ZF27 (C30): | −3.3148E−05 | ZF28 (C31): | −4.1400E−06 | ZF31 (C34): | 8.0569E−06 |
| ZF32 (C35): | 6.3175E−06 | ZF35 (C38): | 1.6542E−06 | ZF36 (C39): | 9.0622E−07 |
| ZF37 (C40): | −4.5173E−08 | | | | |

TABLE 6
Surface Type S-5 Fringe Zernike Surface Curvature = 0.654189E−03

| | | | | | |
|---|---|---|---|---|---|
| NRADIUS (C2): | 1.1968E+02 | ZF1 (C4): | 3.8195E−02 | ZF4 (C7): | 5.7633E−02 |
| ZF5 (C8): | 2.1949E−01 | ZF8 (C11): | 9.3798E−03 | ZF9 (C12): | 5.7526E−02 |
| ZF11 (C14): | 3.2503E−02 | ZF12 (C15): | 7.5562E−03 | ZF15 (C18): | −1.6091E−03 |
| ZF16 (C19): | 8.6571E−04 | ZF17 (C20): | −1.0011E−03 | ZF20 (C23): | 7.4004E−04 |
| ZF21 (C24): | 1.2404E−04 | ZF24 (C27): | −3.8861E−05 | ZF25 (C28): | 2.6211E−05 |
| ZF27 (C30): | −3.2637E−04 | ZF28 (C31): | 5.3275E−05 | ZF31 (C34): | 1.0360E−05 |
| ZF32 (C35): | 4.1451E−06 | ZF35 (C38): | −5.3056E−06 | ZF36 (C39): | 1.2806E−06 |
| ZF37 (C40): | −8.9789E−08 | | | | |

TABLE 7
Surface Type S-6 Fringe Zernike Surface Curvature = 0.940076E−03

| | | | | | |
|---|---|---|---|---|---|
| NRADIUS (C2): | 4.1144E+02 | ZF1 (C4): | 5.8188E−02 | ZF4 (C7): | 8.8395E−02 |
| ZF5 (C8): | 6.3399E−01 | ZF8 (C11): | 1.2365E−01 | ZF9 (C12): | 1.5517E−01 |
| ZF11 (C14): | −8.9447E−02 | ZF12 (C15): | 2.7557E−02 | ZF15 (C18): | 3.0854E−03 |
| ZF16 (C19): | 9.0677E−03 | ZF17 (C20): | −3.1901E−03 | ZF20 (C23): | −1.2080E−03 |
| ZF21 (C24): | 9.7690E−04 | ZF24 (C27): | 1.3927E−05 | ZF25 (C28): | 4.9013E−04 |
| ZF27 (C30): | −1.0696E−03 | ZF28 (C31): | −2.1102E−05 | ZF31 (C34): | −5.0251E−05 |
| ZF32 (C35): | 5.8245E−06 | ZF35 (C38): | −1.9687E−05 | ZF36 (C39): | 2.4870E−05 |

TABLE 8
DECENTERING CONSTANTS

| DE- | | | | | | |
|---|---|---|---|---|---|---|
| CEN- | | | | | | |
| TER | X | Y | Z | ALPHA | BETA | GAMMA |
| D(1) | 0.0000 | 44.7044 | 0.0000 | 0.0000 | 0.0000 | 0.0000 (RETU) |
| D(2) | 0.0000 | −41.7227 | 0.0000 | −5.5663 | 0.0000 | 0.0000 (RETU) |
| D(3) | 0.0000 | 75.2596 | 0.0000 | 0.0000 | 0.0000 | 0.0000 (RETU) |
| D(4) | 0.0000 | 44.7044 | 0.0000 | 1.4526 | 0.0000 | 0.0000 (RETU) |
| D(5) | 0.0000 | 75.2596 | 0.0000 | 0.1791 | 0.0000 | 0.0000 (RETU) |
| D(6) | 0.0000 | 120.8305 | 0.0000 | −1.5435 | 0.0000 | 0.0000 (RETU) |
| D(7) | 0.0000 | 75.2596 | 0.0000 | 0.0000 | 0.0000 | 0.0000 (RETU) |

TABLE 9
Order of operations for decenters and tilts

| | | |
|---|---|---|
| DECENTER | | DISPLACE (X, Y, Z) |
| | | TILT (ALPHA, BETA, GAMMA) |
| | | REFRACT AT SURFACE |
| | | THICKNESS TO NEXT SURFACE |
| DECENTER | RETU | DECENTER (X, Y, Z, ALPHA, BETA, |
| & RETURN | | GAMMA) |
| | | REFRACT AT SURFACE |
| | | RETURN (-GAMMA, -BETA, -ALPHA, |
| | | -Z, -Y, -X) |
| | | THICKNESS TO NEXT SURFACE |

I claim:

1. A catoptric optical system including a plurality of mirrors arranged along an axis, the system comprising:
a first mirror situated to receive light propagating away from the axis from a point on an object surface, wherein the point on the object surface is displaced from the axis along a first direction;
a second mirror on which light from the first mirror is incident;
a third mirror on which light from the second mirror is incident;
a fourth mirror, arranged between the second mirror and the object surface, on which light from the third mirror is incident;
a fifth mirror including a first aperture, on which light from the fourth mirror is incident; and
a sixth mirror including a second aperture, on which light from the fifth mirror is incident;
wherein the light from the fourth mirror passes through the second aperture of the sixth mirror and then is incident on the fifth mirror;
wherein the light from the sixth mirror passes through the first aperture of the fifth mirror and then is incident on a point on an image surface that is displaced from the axis along a second direction opposite the first direction; and
wherein the light from the fourth mirror forms an intermediate image between the first mirror and the third mirror.

2. The catoptric optical system of claim 1, wherein a first separation between the axis and a farthest position from the axis in a first reflective region where the fourth mirror reflects the light is smaller than a second separation between the axis and a farthest position from the axis in a second reflective region where the fifth mirror reflects the light.

3. The catoptric optical system of claim 2, wherein a third separation between the axis and a closest position from the axis in the first reflective region is smaller than a fourth separation between the axis and a farthest position from the axis in a third reflective region where the third mirror reflects the light.

4. The catoptric optical system of claim 1, wherein a first separation between the axis and a farthest position in a first reflective region where the third mirror reflects the light is larger than a second separation between the axis and a closest position from the axis in a second reflective region where the fourth mirror reflects the light.

5. The catoptric optical system of claim 1, wherein a first separation between the axis and a farthest position from the axis in a first reflective region where the first mirror reflects the light is larger than a second separation between the axis and a farthest position in a field of view region in the object surface.

6. The catoptric optical system of claim 1, wherein reflected light from the first mirror is directed toward the axis.

7. The catoptric optical system of claim 6, wherein reflected light from the second mirror is directed away from the axis.

8. The catoptric optical system of claim 7, wherein reflected light from the third mirror is directed away from the axis.

9. The catoptric optical system of claim 1, wherein at least one of the first and second apertures is decentered with respect to the axis.

10. The catoptric optical system of claim 1, wherein the fifth and sixth mirrors are decentered and/or tilted with respect to the axis.

11. The catoptric optical system of claim 1, wherein the first mirror comprises a concave reflective surface.

12. The catoptric optical system of claim 1, wherein the first and second apertures are decentered with respect to the axis.

13. The catoptric optical system of claim 1, wherein the second and third mirrors are positioned between the first and fourth mirrors along the axis.

14. The catoptric optical system of claim 13, wherein:
each of the first and fourth mirrors comprise a concave reflective surface; and
each of the second and third mirrors comprise a convex reflective surface.

15. The catoptric optical system of claim 1, wherein reflected light from the fourth mirror is directed towards the axis.

16. The catoptric optical system of claim 15, wherein the fourth mirror comprises a concave reflective surface.

17. The catoptric optical system of claim 1, wherein reflected light from the fifth mirror towards the sixth mirror is divergent.

18. An exposure apparatus comprising:
an illumination optical system that illuminates a mask pattern with light from a light source; and
the catoptric optical system of claim 1 that forms an image of the mask pattern onto a substrate.

19. An exposure method comprising:
illuminating a mask pattern with light from a light source; and
forming an image of the mask pattern by using the catoptric optical system of claim 1.

20. A device manufacturing method comprising:
exposing a pattern onto a substrate having a photoresist layer using the exposure method of claim 19;
developing the photoresist layer to form a mask layer having a shape corresponding to the pattern; and
processing the substrate via the mask layer.

21. The catoptric optical system of claim 1, wherein the light from the second mirror crosses the axis and is then incident to the third mirror.

22. The catoptric optical system of claim 1, wherein the third mirror defines an aperture stop.

23. The catoptric optical system of claim 1, wherein the light from the second mirror crosses the axis and is then incident to the third mirror, and the third mirror defines an aperture stop.

24. An optical system for forming an image of an object that is on an object surface, the image being formed on an image surface displaced from the object surface along a first axis, the optical system comprising:
a first imaging optical system situated to form an intermediate image of a first point on the object surface, the first point displaced from the first axis along a first direction wherein the intermediate image is formed at a second point displaced from the first axis along a second direction which is opposite of the first direction; and
a second imaging optical system situated to form an image of the intermediate image of the second point at a third point displaced from the first axis along the second direction, the image of the intermediate image of the second point being formed on the image surface.

25. The optical system of claim 24, wherein no intermediate image is formed in the second imaging optical system.

26. The optical system of claim 24, wherein the second imaging optical system includes an optical element decentered from the first axis.

27. The optical system of claim 24, wherein the second imaging optical system includes two mirrors.

28. The optical system of claim 27, wherein the second imaging optical system has two mirrors and each of the two mirrors of the second imaging optical system comprises an aperture.

29. The optical system of claim 27, wherein the first imaging optical system includes optical elements that define the first axis.

30. The optical system of claim 29, wherein the first imaging optical system is a coaxial optical system.

31. An optical system arranged between a first surface and a second surface, the optical system comprising:
a first optical system situated between the first surface and the second surface and defining an optical axis; and
a second optical system situated between the first surface and the second surface to form an image of an object;
wherein the object and the image are positioned on the same side with respect to the optical axis.

32. The optical system of claim 31, wherein the second optical system includes an optical element that is decentered from the optical axis.

33. The optical system of claim 31, wherein no intermediate image is formed in the second optical system.

34. An optical system arranged between a first surface and a second surface, the optical system comprising:
a first optical system situated between the first surface and the second surface and defining an optical axis; and
a second optical system situated between the first surface and the second surface to form an image of an object,
wherein the second optical system includes an optical element that is decentered from the optical axis.

35. The optical system of claim 34, wherein the second optical system includes two optical elements that are decentered from the optical axis.

36. The optical system of claim 35, wherein the second optical system consists of two optical elements.
